(19) United States
(12) Patent Application Publication
(10) Pub. No.: US 2009/0000810 A1
(43) Pub. Date: Jan. 1, 2009

(54) PRINTED CIRCUIT BOARD

(75) Inventor: Yuuichi Koga, Hachioji-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/146,343

(22) Filed: Jun. 25, 2008

(30) Foreign Application Priority Data
Jun. 29, 2007 (JP) 2007-173361

(51) Int. Cl. H05K 1/02

(52) U.S. Cl. 174/255

(57) ABSTRACT

According to one embodiment, there is provided a printed wiring board includes a mounting surface for mounting an electronic component, a first component mounted on the mounting surface, an index portion provided on the mounting surface for defining a mounting position Pa of a second component being mounted on the mounting surface in a process after the first component is mounted, the index portion including two direction positions on the mounting surface, and the second component mounted on the mounting surface based on the index portion.

### CROSS-REFERENCE TO RELATED APPLICATIONS

This application is based upon and claims the benefit of priority from Japanese Patent Application No. 2007-173361, filed Jun. 29, 2007, the entire contents of which are incorporated herein by reference.

### BACKGROUND

1. Field

One embodiment of the present invention relates to a printed wiring board applied to a portable electronic apparatus, for example.

2. Description of the Related Art

A printed wiring board mounted with a memory card connector, applied to a portable electronic apparatus, is mounted with a bonding component such as an insulator to protect a memory card from short-circuit and external impact. This kind of sheet-like bonding component is excluded from automated mounting component by a surface mount technology (SMT). In a component mounting process of the printed wiring board, the bonding component is manually bonded as a post-mount component to a predetermined position of the printed wiring board. For this reason, in the conventional case, a mark indicating a mounting position is previously printed by silk screen printing in order to prevent misalignment of the mounting position. Thereafter, the post-mount component such as insulator is bonded to a position indicated by the foregoing mark.

However, the foregoing silk screen printing causes the following problem arises. Specifically, when the silk screen printing is performed in a process of manufacturing a printed wiring board, the number of processes will be increased, and in addition, there is a possibility of giving a bad influence to soldering printability. Thus, a printed wiring board excellent in economy has been studied without carrying out the silk screen printing. In this case where the silk screen printing is not performed, there is no index of the mounting position of the post-mount component on the printed wiring board; as a result, misalignment of the mounting position will occur.

For example, Jpn. Pat. Appin. KOKAI Publication No. 2002-204041 discloses a mounting position detecting structure for electric components as a technique of giving a component mounting position as an index without carrying out silk screen printing. According to the technique, a plurality of detection patterns linearly extending along the outer side of a square outside of a square-shaped chip-type electronic component. However, if the foregoing technique is applied to the mounting position index of the post-mounting component, the following problem arises. Specifically, it is difficult to distinguish the detection patterns linearly extending from other various wiring patterns. For this reason, this is a factor of causing the misalignment of the mounting position, and the detection pattern dose not function as an index of a correct mounting position of the post-mounting component.

As described above, if a printed wiring board is realized without carrying out silk screen printing, there is a problem of causing misalignment of the mounting position of the post-mounting component in the conventional case.

According to one aspect of the present invention, there is provided a printed wiring board comprising:

an electronic component mounting surface;

a first component mounted on the mounting surface;

an index portion provided on the mounting surface, and defining a mounting position of a component mounted on the mounting surface in a process after the first component is mounted by two direction lines along the mounting surface; and

a second component mounted on the mounting surface based on the index portion.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view showing principal parts of a printed wiring board according to a first embodiment of the present invention;

FIG. 2 is a plan view showing a modification example of an index conductor of the printed wiring board according to the first embodiment;

FIG. 3 is a plan view showing principal parts of a printed wiring board according to a second embodiment of the present invention;

FIG. 4 is a plan view showing principal parts of a printed wiring board according to a third embodiment of the present invention; and

FIG. 5 is a perspective view to explain a mounting example of the printed wiring board according to the third embodiment.

### DETAILED DESCRIPTION

Various embodiments according to the present invention will be hereinafter described with reference to the accompanying drawings. In general, according to one embodiment of the invention, there is provided a printed wiring board comprising:

an electronic component mounting surface;

a first component mounted on the mounting surface;

an index portion provided on the mounting surface, and defining a mounting position of a component mounted on the mounting surface in a process after the first component is mounted by two direction lines along the mounting surface; and

a second component mounted on the mounting surface based on the index portion.

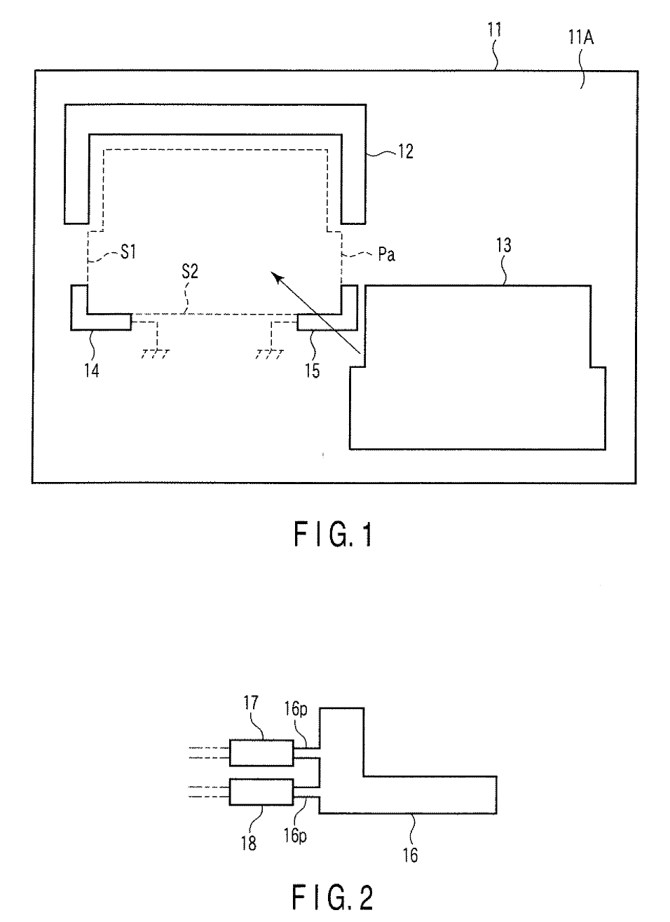

FIG. 1 shows the configuration of a printed wiring board according to a first embodiment of the present invention.

As shown in FIG. 1, a printed wiring board 11 according to the first embodiment of the present invention includes a first component (pre-mounting component) 12, a second component (post-mounting component) 13, index portions 14 and 15. The first component 12 is mounted on a mounting surface 11A of the printed wiring board 11. The second component 13 is mounted on the mounting surface 11A in a process after the first component 12 is mounted. The mounting surface 11A is provided with a wiring pattern forming a circuit of the first component 12, but, the wiring pattern is omitted in FIG. 1 for preventing the complexity of the drawing.

The first component 12 pre-mounted on the mounting surface 11A is a memory card connector, for example. Hereinafter, the memory card connector is referred to as a card connector. An external memory card (not shown) is detachably connected to the card connector 12 and held on the board 11 in a manner described later. The card connector 12 is an automatically mounted component (pre-mounting component) by SMT (surface mount technology).

The second component 13 is a mounting component comprising a convex insulating sheet for holding the memory card. Hereinafter, the second component 13 is referred to as insulator. The insulator 13 is bonded to a mounting position Pa of the mounting surface 11A defined by index portions 14 and 15 so that the insulator 13 is mounted on the mounting surface 11A as a post-mounting component. In this case, the mounting position Pa is defined by a component mounting position of the card connector 12.

The index portions 14 and 15 each comprise an L-letter shaped conductor pattern defining perpendicular two sides S1, S2 of the mounting position Pa. Hereinafter, the index portions 14 and 15 are referred to as index conductor. The index conductors 14 and 15 are pattern-formed on the mounting surface 11A at the same time of forming of the wiring patterns (not shown). The foregoing two index conductors 14 and 15 each form an L-letter shaped index on both ends of one side S2 of the mounting position Pa. Further, one index conductor 14 is also used as an index for defining the side S1 perpendicular to the side S2. Thus, these index conductors 14, 15 are used as indexes showing mounting start ends of the insulator 13. The index conductors 14 and 15 may be connected to a ground level so that they are supplied with low impedance signal attribute. The conductors 14, 15 may also be connected to a power supply (VCC) line with the low impedance signal attribute. This is because of reducing electromagnetic hindrance to the memory card mounted to the card connector 12.

When the insulator 13 is mounted on the mounting position Pa of the mounting surface 11A, the insulator 13 is bonded to the mounting position Pa based on the mount start end indicated by the two index conductors 14 and 15. In this way, it is possible to readily mount (bond) the insulator 13 to the correct mounting position Pa.

As described above, the post-component 13 is manually mounted to the correct mounting position Pa in the printed wiring board 11 without carrying out the prior art silk screen printing.

FIG. 2 shows a modification of the index conductor described in the first embodiment shown in FIG. 1. In this modified embodiment, the index conductor 16 is also used as one element of the wiring pattern. The L-letter shaped index conductor 16 shown in FIG. 2 has wiring patterns 16p each extending to the outside of the pattern conductor 16; for example. The wiring patterns lp each form a part of a circuit of respective chip components 17 and 18. Incidentally, these chip components 17 and 18 are automatic mounting components (pre-mounting components) by SMT.

The foregoing configuration of FIG. 2 may be provided for a high-density wiring and the component mounting may be achieved effectively by using the thus configured index conductor 16.

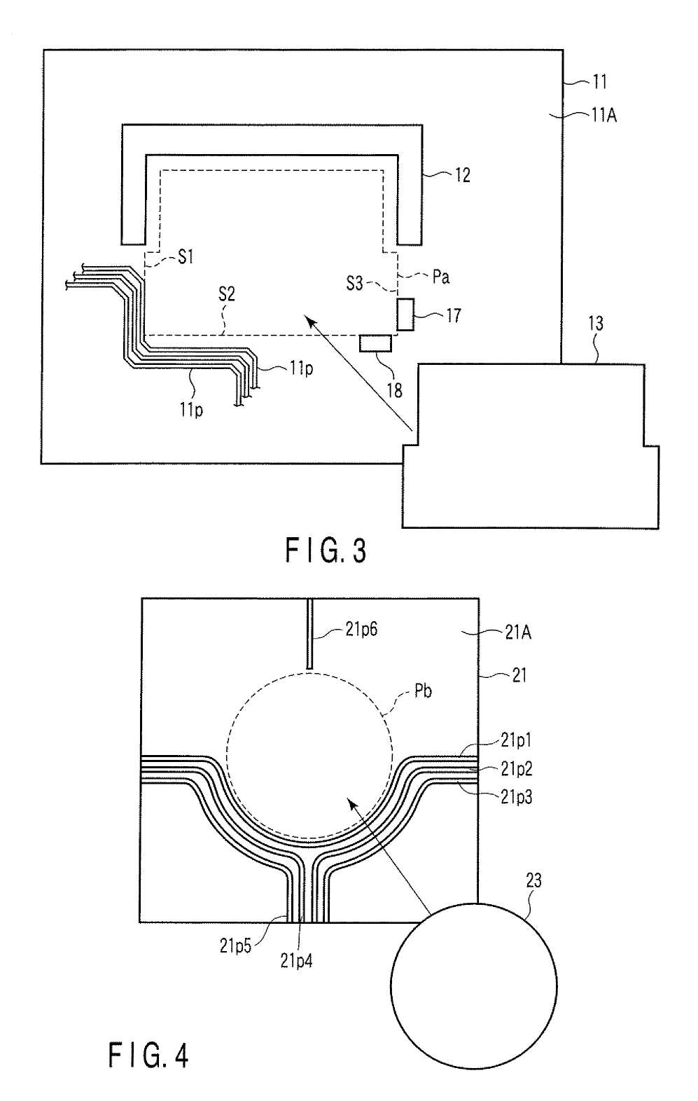

FIG. 3 shows a configuration of a second embodiment of the present invention. According to the second embodiment, wiring patterns lip, chip components 17 and 18 are used as index portions in place of the index conductors 14 and 15 of the first embodiment.

The foregoing wiring patterns 11p and the component mounting elements such as chip components 17 and 18 are used as index portions for defining the perpendicular two sides S1, S2 of a post-mounting component (insulator) 13. In this embodiment of FIG. 3, the component 17 may also be used for defining another side S3 of the insulator 13. In this way, it is possible to readily mount (bond) the post-mounting component 13 to a correct mounting position Pa on the printed wiring board 11 without carrying out the prior art silk screen printing.

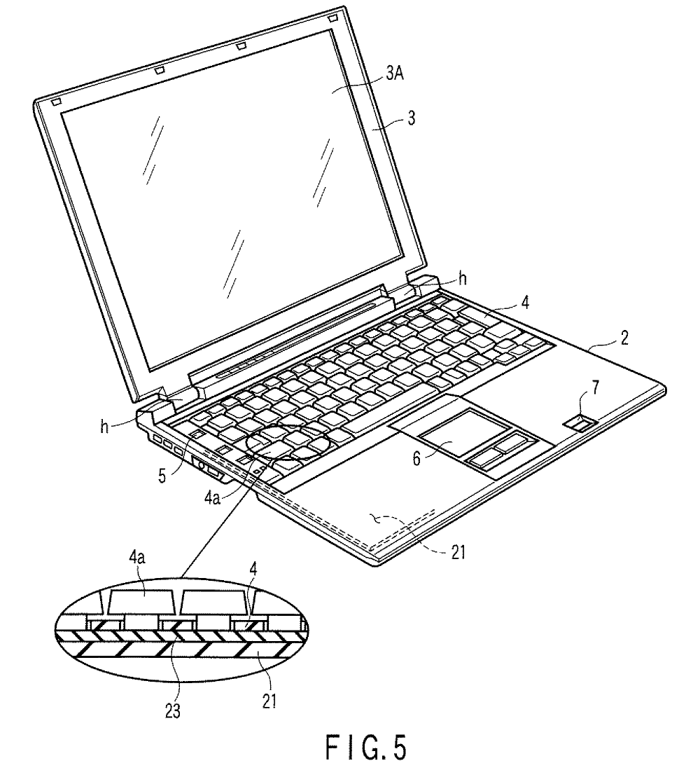

FIG. 4 and FIG. 5 show a third embodiment of the present invention. According to the third embodiment, a post-mounting component 23, that is, insulator 23 is used as a shock absorber pad.

As shown in FIG. 4, a printed wiring board 21 according to the third embodiment of the present invention includes a mounting surface 21A, on which the circular shaped post-mounting component 23 is mounted and a plurality of wiring patterns 21p1 to 21p6 are printed. Of these wiring patterns, patterns 21p1 and 21p6 act as index portions. Incidentally, the mounting surface 21A is mounted with various electronic components, but only the mounting area Pb for the post-mounting component 23 is shown in FIG. 4, and the mounting portions of electronic components are omitted in the figure.

The wiring pattern 21p1 forming one index portion is formed by a semi-circular curve wiring pattern and another index portion is defined by the linear wiring pattern 21p6, and thereby, the mounting position Pb of the post-mounting component 23 is defined. The wiring patterns 21p1 to 21p6 including the patterns 21p1 and 21p6 defining the mounting position of the post-mounting component 23 may be wiring patterns actually forming circuits. However, the patterns may be included with a dummy wiring pattern which is formed for defining the mounting position Pb, for example.

The post-mounting component 23 is a bonding component formed of a circular insulating sheet, and hereinafter, referred to as an insulator 23. The insulator 23 is bonded to the mounting position Pb defined by a plurality of wiring patterns 21p1, 21p6 forming the index portions of the insulator 23 to be mounted or bonded on the mounting surface 21A. The insulator 23 bonded to the mounting position Pb on the mounting surface 21A functions as a key-shock absorber pad, for example as described later. In this case, the wiring pattern 21p1 may be used alone for defining the mounting position Pb of the insulator 23. However, when the pattern 21p1 is used in combination with the pattern 21p6, the insulator 23 will be mounted at a strict correct position, since the pattern 21p6 may define the upper portion of the insulator 23 in the mounting position Pb.

FIG. 5 shows an example of mounting a circuit board comprising the printed wiring board 21 including the insulator 23 shown in FIG. 4. A portable computer shown in FIG. 5 comprises a computer main body 2 and a display housing 3. The computer main body 2 includes a keyboard 4 including a plurality of keys 4a, a power button 5, a touch pad 6 and a fingerprint sensor 7. The display housing 3 includes an LCD 3A, which is rotatably supported by hinges h to the computer main body 2. The computer main body 2 has a built-in circuit board configured using the printed wiring board 21 having the insulator 23 as the post-mounting component bonded to the mounting position Pb as shown in FIG. 4.

According to the configuration shown in FIG. 5, the insulator 23 bonded to the mounting position Pb of the printed wiring board 21 functions as a shock absorber pad with respect to the keys 4a when the keys 4a are pressed down on the keyboard 4 provided on the surface of the computer main body 2.

According to the foregoing configuration, it is possible to provide a printed circuit board, which is prepared by manually bonding the post-mounting component to the correct mounting position without carrying out the prior art silk screen printing. The present invention is not limited to the foregoing embodiments. Various applications may be made without departing from the subject matter of the present invention. For example, the foregoing embodiments may be combined.

While certain embodiments of the invention have been described, there embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

What is claimed is:

1. A printed wiring board comprising:
a mounting surface for mounting an electronic component;
a first component mounted on the mounting surface;
an index portion provided on the mounting surface for defining a mounting position of a second component mounted on the mounting surface in a process after the first component is mounted, the index portion including two direction positions on the mounting surface; and
the second component mounted on the mounting surface based on the index portion.

2. The board according to claim 1, wherein the second component is a sheet-like insulating material being bonded to the mounting surface.

3. The board according to claim 1, wherein the index portion indicates at least perpendicular two sides of the mounting position.

4. The board according to claim 1, wherein the index portion comprises a conductor pattern.

5. The board according to claim 1, wherein the index portion comprises a wiring pattern forming a circuit of the electronic component.

6. The board according to claim 1, wherein the index portion comprises a chip component included in the electronic component.

7. The board according to claim 1, wherein the index portion comprises a conductor pattern supplied with low impedance signal attribute.

8. The board according to claim 1, wherein the index portion comprises a plurality of L-letter shaped conductor patterns.

9. The board according to claim 2, wherein the index portion forms an L-letter shaped index at both ends of one side of the mounting position, and the L-letter shaped index indicates a mounting start end of the insulator material.

10. The board according to claim 1, wherein the mounting position of the second component is defined with respect to a mounting position of the first component on the mounting surface.
